(19) United States
(12) Patent Application Publication
(10) Pub. No.: US 2026/0164555 A1
(43) Pub. Date: Jun. 11, 2026

(54) CARRIER SUBSTRATE AND MANUFACTURING METHOD THEREOF

(71) Applicant: AaltoSemi Inc., Nanjing City (CN)

(72) Inventors: Yin-Ju CHEN, Nanjing City (CN); Min-Yao CHEN, Nanjing City (CN); Sung-Kun LIN, Nanjing City (CN)

(73) Assignee: AaltoSemi Inc., Nanjing City (CN)

(21) Appl. No.: 19/179,675

(22) Filed: Apr. 15, 2025

(30) Foreign Application Priority Data
Jul. 4, 2024 (CN) 202410891423.0

(51) Int. Cl. H05K 1/14; H05K 1/11; H05K 3/46

(52) U.S. Cl. CPC H05K 1/144; H05K 1/115; H05K 3/4614; H05K 2201/09563; H05K 2201/09854

(57) ABSTRACT

Provided are a carrier substrate and a manufacturing method thereof. A carrier substrate is made by stacking a plurality of glass board structures to form a composite board having through holes, the wiring layers are formed on surfaces of opposite sides of the composite board, and conductive pillars electrically connected to the wiring layers are formed in the through holes. Therefore, by stacking the multiple thinner glass board structures, the composite board that meets the thinning requirements can be manufactured.

### CROSS-REFERENCE TO RELATED APPLICATIONS

This application claims priority to Chinese Patent Application No. 202410891423.0, filed on Jul. 4, 2024, the entire contents of which are incorporated herein by reference and made a part of this specification.

### BACKGROUND

### 1. Technical Field

The present disclosure relates to a semiconductor packaging technology, and more particularly, to a carrier substrate capable of improving reliability and manufacturing method thereof.

### 2. Description of Related Art

With the vigorous development of portable electronic products in recent years, various related products have gradually moved towards the trend of high density, high performance, lightness, thinness, shortness and smallness. Therefore, various types of packaging processes have also been innovated in order to meet the requirements of lightness, thinness, shortness and high density.

In the current packaging process, as the circuit pitch of semiconductor chips becomes smaller, packaging substrates made of organic board cannot be combined with the development of semiconductor chips, thereby packaging integration becomes difficult.

For example, the difference in coefficient of thermal expansion (CTE) between the semiconductor chip and the organic board of the packaging substrate is very large (the CTE of the semiconductor chip is about 3 ppm/° C., and the CTE of the organic board is about 18 ppm/° C.), resulting in the mismatch of the CTE between the semiconductor chip and the organic board, and a stress gradient toward the edge would be generated by the organic board, resulting in residual thermal stress and warpage. Accordingly, the conventional packaging substrates have poor thermal stress resistance under harsh environmental conditions, resulting in decreased reliability.

Therefore, there is a need for addressing the aforementioned shortcomings in the prior art.

### SUMMARY

In view of the aforementioned shortcomings of the prior art, the present disclosure provides a carrier substrate which comprises: a plurality of first board structure containing silicon and having a plurality of first vias; a second board structure containing silicon and having a plurality of second vias; and a third board structure containing silicon and having a third via, wherein the plurality of first board structures, the second board structure and the third board structure are stacked to form a composite board, the plurality of first board structures are positioned between the second board structure and the third board structure, and each of the first vias, the second vias and the third vias are correspondingly connected to each other to form a through hole; wiring layers formed on two opposite sides of the composite board; and a plurality of conductive pillars each formed in the through holes are electrically connected to the wiring layer.

The present disclosure also provides a method of manufacturing a carrier substrate, and the method comprises: providing a plurality of first board structure containing silicon and having a plurality of first vias; a second board structure containing silicon and having a plurality of second vias; and a third board structure containing silicon and having a plurality of third vias; stacking the plurality of first board structures, the second board structure and the third board structure to form a composite board, wherein the plurality of first board structures are interposed between the second board structure and the third board structure, and each of the first vias, the second vias and the third vias are connected to each other to form a through hole; and forming wiring layers on two opposite sides of the composite board, and forming at least one conductive pillar electrically connected to the wiring layers in the through hole.

In the aforementioned carrier substrate and method, the plurality of first board structures, the second board structure and the third board structure include glass board.

In the aforementioned carrier substrate and method, the plurality of first board structures, the second board structure and/or the third board structure further have circuit layers electrically connected to the conductive pillars.

In the aforementioned carrier substrate and method, the plurality of first board structures, the second board structure and the third board structure are bonded to each other by insulating layers.

In the aforementioned carrier substrate and method, the first board structure comprises a first board body with the first vias penetrating the first board structure, and first circuit layers are formed on two opposite surfaces of the first board body. For example, first insulating layers covering the first circuit layers are formed on the two opposite surfaces of the first board body.

In the aforementioned carrier substrate and method, the second board structure comprises a second board body, the second vias penetrating the second board structure, and a second circuit layer formed on one of two opposite surfaces of the second board body. For example, second insulating layers are formed on two opposite surfaces of the second board body, and thus the second circuit layer is covered by the second insulating layer on one of the two opposite surfaces.

In the aforementioned carrier substrate and method, the third board structure comprises a third board body, the third vias penetrating the third board structure, and a third circuit layer formed on one of two opposite surfaces of the third board body. For example, third insulating layers are formed on two opposite surfaces of the third board body, and thus the third circuit layer is covered by the third insulating layer on one of the two opposite surfaces.

As can be understood from the above, in the carrier substrate and manufacturing method of the present disclosure, the composite board is manufactured by stacking multiple thinner first board structures, second board structure and third board structure to meet the thinning requirements. Accordingly, the structure stability of the carrier structure can be greatly improved through silicon material having the characteristic of resisting warping and deformation. For example, the stress on each layer of the board structure is concentrically distributed, instead of stress gradients toward the edges generated by the conventional organic board. Therefore, compared with the prior art, the carrier substrate of the present disclosure has better thermal stress resistance under harsh environmental conditions, thereby improving reliability.

### BRIEF DESCRIPTION OF THE DRAWINGS

The exemplary embodiments herein may be better understood by referring to the following description in conjunction with the accompanying drawings in which like reference numerals indicate identically or functionally similar elements, of which:

FIG. 1A to FIG. 1C are schematic cross-sectional views of an exemplary manufacturing method of the first board structure of the carrier substrate of the present disclosure.

FIG. 2A to FIG. 2C are schematic cross-sectional views of an exemplary manufacturing method of the second board structure of the carrier substrate of the present disclosure.

FIG. 3A to FIG. 3C are schematic cross-sectional views of an exemplary manufacturing method of the third board structure of the carrier substrate of the present disclosure.

FIG. 4A to FIG. 4C are schematic cross-sectional views of an exemplary manufacturing method of the carrier substrate of the present disclosure.

### DETAILED DESCRIPTION

Implementations of the present disclosure are described below by exemplary embodiments. Other advantages and technical effects of the present disclosure can be readily understood by one of ordinary skill in the art upon reading the disclosure of this specification.

It should be noted that the structures, ratios, sizes shown in the drawings appended hereto are provided in conjunction with the disclosure of this specification in order to facilitate understanding by those skilled in the art. They are not intended, in any way, to limit the techniques and methods of this disclosure. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “first,” “second,” “third,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

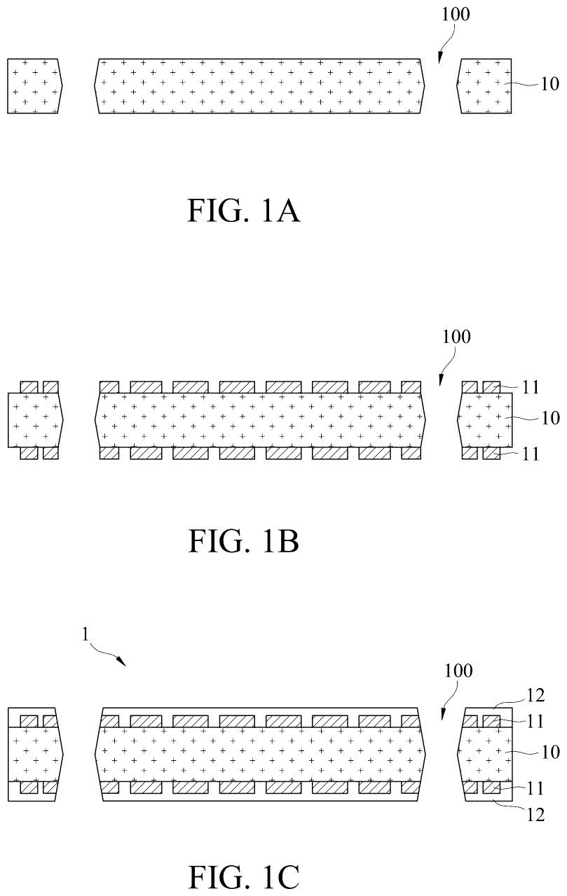

FIG. 1A to FIG. 1C are schematic cross-sectional views of an exemplary manufacturing method of a first board structure 1 of the carrier substrate of the present disclosure.

As shown in FIG. 1A, a first board body 10 is provided, which has a plurality of first vias 100 penetrating the first board body 10.

In one embodiment, the first board body 10 is a board containing silicon, such as glass or other boards.

Furthermore, the first vias 100 are in a shape of a double conical hole like an hourglass shape, but in other exemplary embodiments, the first vias 100 can also be in a shape of a straight cylinder, a cone, or other hole shapes. For example, a plurality of first vias 100 are formed by laser.

As shown in FIG. 1B, first circuit layers 11 are formed on two opposite surfaces of the first board body 10.

In one embodiment, the first circuit layers 11 may adopt a redistribution layer (RDL) specification. For example, dry films are attached to the opposite surfaces of the first board body 10, and then the first circuit layers 11 are formed by a patterning process with exposure, development and electroplating. In an exemplary embodiment, a material forming the first circuit layers 11 is copper.

As shown in FIG. 1C, first insulating layers 12 are formed on the opposite surfaces of the first board body 10 after the first circuit layers 11 are formed and the dry films are removed, and thus the first circuit layers 11 are covered by the first insulating layers 12.

In one exemplary embodiment, the first insulating layers 12 are photosensitive layers such as photo imageable coverlays (PICL), which is in an uncured state. Further, the first vias 100 are extended through the first insulating layers 12 after the first insulating layers 12 is exposed and developed.

The first board structure 1 obtained according to the above exemplary manufacturing method includes the first board body 10, the first vias 100 penetrating the first board structure 1, and the first circuit layers 11 formed on the two opposite surfaces of the first board body 10.

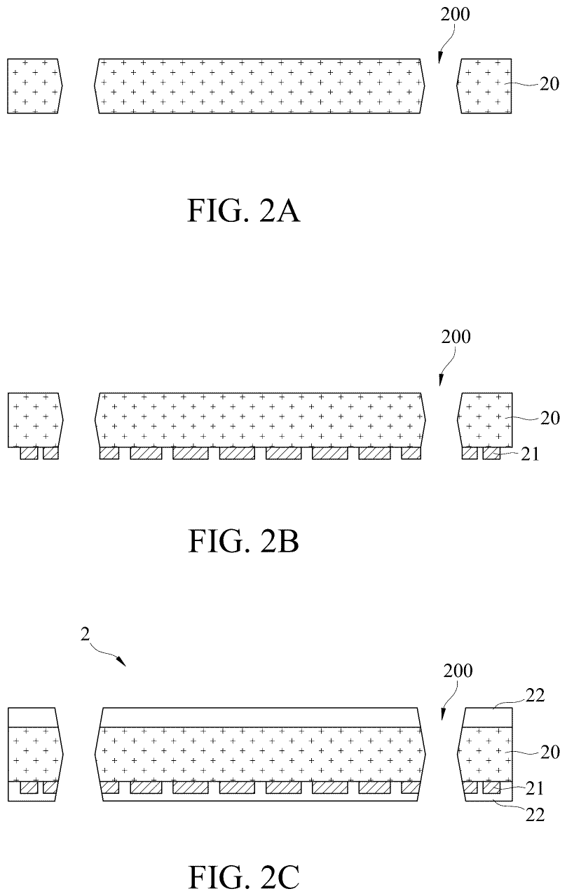

FIG. 2A to FIG. 2C are schematic cross-sectional views of an exemplary manufacturing method of a second board structure 2 of the carrier substrate of the present disclosure.

As shown in FIG. 2A, a second board body 20 having a plurality of second vias 200 is provided.

In one embodiment, the second board body 20 is a board containing silicon, such as glass or other boards.

Furthermore, the second vias 200 are in a shape of a double conical hole like an hourglass shape, but in other embodiments, the second vias 200 can also be in a shape of a straight cylinder, a cone, or other hole shapes. For example, a plurality of second vias 200 are formed by laser.

As shown in FIG. 2B, a second circuit layer 21 is formed on one surface (such as bottom surface) of the second board body 20.

In one embodiment, the second circuit layers 21 may adopt a redistribution layer (RDL) specification. For example, a dry film is attached to the bottom surface of the second board body 20, and then the second circuit layer 21 is formed by a patterning process with exposure, development and electroplating. In an exemplary embodiment, the second circuit layer 21 is formed by copper.

As shown in FIG. 2C, a second insulating layer 22 is formed on opposite surfaces of the second board body 20 after the second circuit layer 21 is formed and the dry film is removed, and thus the second circuit layer 21 is covered by the second insulating layer 22 on one of the opposite surfaces.

In one exemplary embodiment, the second insulating layer 22 is a photosensitive layer such as a photo imageable coverlay (PICL), which is in an uncured state. Further, the second vias 200 are extended through the second insulating layer 22 after the second insulating layer 22 is exposed and developed.

The second board structure 2 obtained according to the above manufacturing method includes the second board body 20, the second vias 200 penetrating the second board structure 2, and the second circuit layer 21 formed on one surface of the second board body 20.

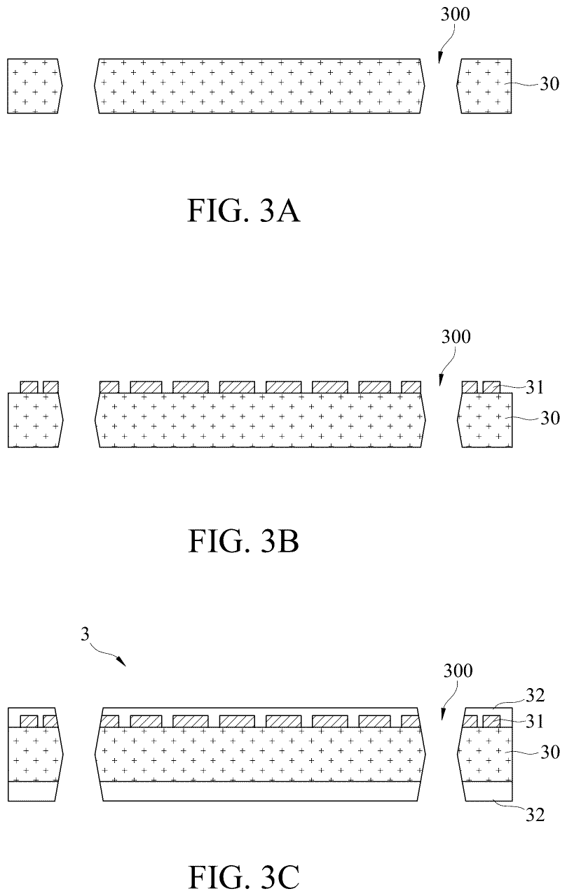

FIG. 3A to FIG. 3C are schematic cross-sectional views of the manufacturing method of a third board structure 3 of the carrier substrate of the present disclosure.

As shown in FIG. 3A, a third board body 30 having a plurality of third vias 300 is provided.

In one embodiment, the third board body 30 is a board containing silicon, such as glass or other boards.

Furthermore, the third vias 300 are in a shape of a double conical hole like an hourglass shape, but in other embodiments, the third vias 300 can also be in a shape of a straight cylinder, a cone, or other hole shapes. For example, a plurality of third vias 300 are formed in a manner of laser.

As shown in FIG. 3B, a third circuit layer 31 is formed on one surface (such as top surface) of the third board body 30.

In one embodiment, the third circuit layers 31 may adopt a redistribution layer (RDL) specification. For example, a dry film is attached to the top surface of the third board body 30, and then the third circuit layer 31 is formed by a patterning process with exposure, development and electroplating, and the third circuit layer 31 is formed in copper.

As shown in FIG. 3C, a third insulating layer 32 is formed on opposite surfaces of the third board body 30 after the third circuit layer 31 is formed and the dry film is removed, and thus the third circuit layer 31 is covered by the third insulating layer 32 on one of the opposite surfaces.

In one embodiment, the third insulating layer 32 is a photosensitive layer such as a photo imageable coverlay (PICL), which is in an uncured state. Further, the third vias 300 are extended through the third insulating layer 32 after the third insulating layer 32 is exposed and developed.

The third board structure 3 obtained according to the above manufacturing method includes the third board body 30, the third vias 300 penetrating the third board structure 3, and the third circuit layer 31 formed on one surface of the third board body 30.

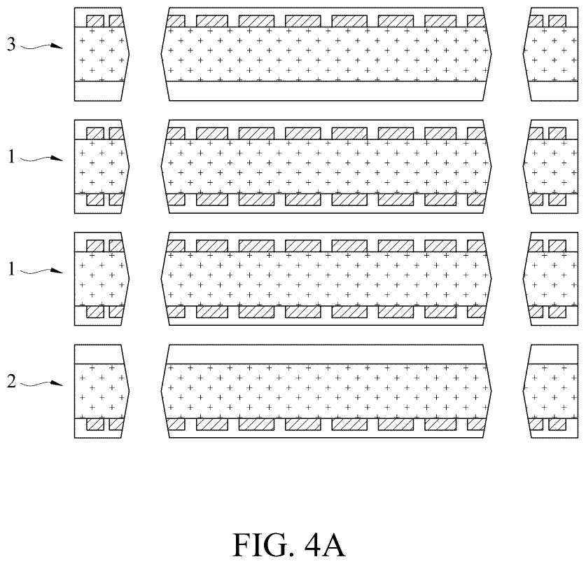

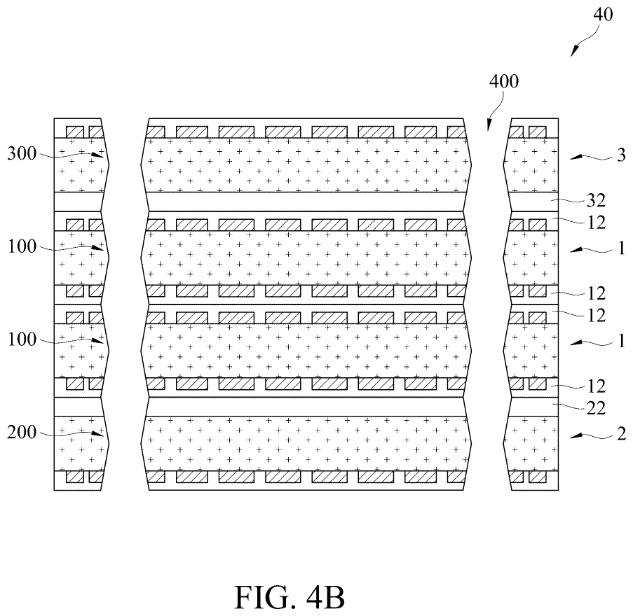

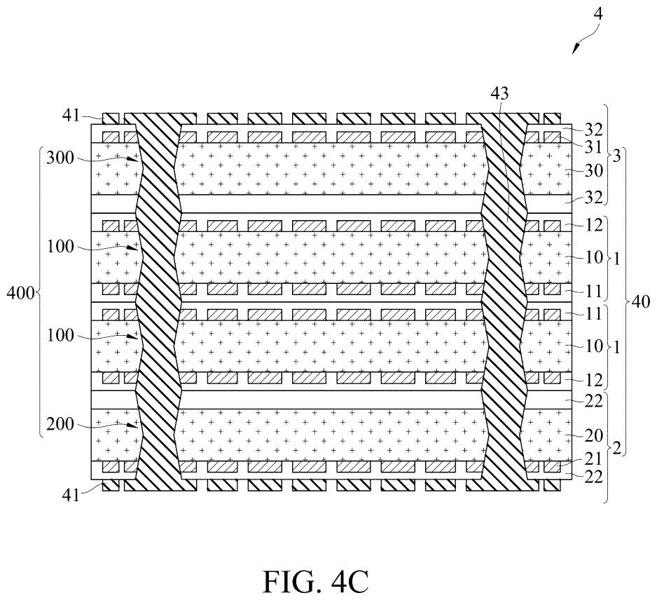

FIG. 4A to FIG. 4C are schematic cross-sectional views of the manufacturing method of a carrier substrate 4 of the present disclosure.

As shown in FIG. 4A, the plurality (such as two) of first board structures 1, the second board structure 2 and the third board structure 3 are provided.

In one embodiment, the first board structures 1, the second board structure 2 and the third board structure 3 are manufactured simultaneously.

As shown in FIG. 4B, the plurality of first board structures 1, the second board structure 2 and the third board structure 3 are stacked to form the composite board 40, and thus the plurality of first board structures 1 are between the second board structure 2 and the third board structure 3. The first vias 100, the second vias 200 and the third vias 300 are correspondingly connected to each other to form through holes 400.

In one embodiment, the first board structures 1, the second board structure 2 and the third board structure 3 are bonded to each other by the first insulating layers 12, the second insulating layer 22 and the third insulating layer 32 by laminating. The second board structure 2 is on a bottom side and the third board structure 3 is on a top side.

As shown in FIG. 4C, wiring layers 41 electrically connected to the second circuit layer 21 and the third circuit layer 31 are formed on surfaces of the second insulating layer 22 and the third insulating layer 32 on opposite sides of the composite board 40. Conductive pillars 43 electrically connected to the wiring layers 41 and the first circuit layers 11 (even the second circuit layer 21 and the third circuit layer 31) are formed in each of the through holes 400. Then, the first insulating layers 12, the second insulating layer 22 and the third insulating layer 32 are cured.

In one embodiment, the wiring layers 41 and the conductive pillars 43 are formed by electroplating, coating or other methods using an RDL process. For example, the conductive pillars 43 are metal pillars such as copper pillars, and thus the conductive pillars 43 become conductive through glass vias (TGV).

Furthermore, a barrier layer and a seed layer (not shown) can be formed on the composite board 40 of the glass body, for example on the first vias, the second vias, the third vias, the second insulating layer and the third insulating layer of the first board structure, the second board structure and the third board structure by sputtering, physical vapor deposition (PVD), chemical vapor deposition (CVD) or atomic layer deposition (ALD). Afterwards, copper materials can be electroplated on the barrier layer and the seed layer, and the barrier layer, the seed layer and copper material on the second insulating layer and the third insulating layer are patterned to integrally form the wiring layers 41 and the conductive pillars 43. For example, if the aspect ratio (A.R) of the through hole 400 is >1:20, the ALD method is preferred. Also, the barrier layer and the seed layer formed in the first vias, the second vias, and the third vias are located between the first board structure, the second board structure, the third board structure and the copper materials. The material forming the barrier layer includes metal nitride (e.g., Ta, TiN, TaN or WN), but is not limited thereto. The material forming the seed layer includes copper, manganese-doped copper or ruthenium, but is not limited thereto. The barrier layer formed in the first vias, the second vias, and the third vias of the first board structure, the second board structure, and the third board structure of glass material can strengthen the bonding strength between the copper material, the glass, and the insulating layer to avoid delamination.

In addition, processes such as solder mask, exposure (EXP), development (DEV) and curing operations (not shown in the figure) can be carried out according to the requirements in the subsequent process, which is hereby stated. It should be understood that the solder mask, the first insulating layers 12, the second insulating layer 22 and the third insulating layer 32 can be cured simultaneously.

Therefore, in the manufacturing method of carrier substrate 4 of the present disclosure, the composite board 40 is manufactured by stacking multiple thinner glass boards (the first board structures 1, the second board structure 2 and the third board structure 3) to meet the thinning requirements. Accordingly, the structure stability of the carrier structure can be greatly improved through silicon material having the characteristic of resisting warping and deformation. For example, the stress on each layer of the board structure is concentrically distributed, instead of stress gradients toward the edges generated by the conventional organic board. Therefore, compared with the prior art, the carrier substrate 4 of the present disclosure has better thermal stress resistance under harsh environmental conditions.

Furthermore, in the manufacturing method of the present disclosure, the first insulating layers 12, the second insulating layer 22 and the third insulating layer are simultaneously solidified after the plurality of first board structures 1, the second board structure 2 and the third board structure 3 are laminated and stacked, and thus the conductive pillars 43 can be manufactured in a single process. Therefore, the manufacturing method of the present disclosure can greatly simplify the process steps, thereby effectively saving process time and reducing manufacturing costs.

The present disclosure also provides the carrier substrate 4, which includes: the plurality of first board structures 1 containing silicon, the second board structure 2 containing silicon, the third board structure 3 containing silicon, at least one wiring layer 41 and at least one conductive pillar 43.

The first board structures 1 have first vias 100.

The second board structure 2 has second vias 200.

The third board structure 3 has third vias 300, and the plurality of first board structures 1, the second board structures 2 and the third board structure 3 are stacked to form the composite board 40, and thus the plurality of first board structures 1 are between the second board structure 2 and the third board structure 3. The first vias 100, the second vias 200 and the third vias 300 are correspondingly connected to each other to form through holes 400.

The wiring layers 41 are formed on the surfaces of opposite sides of the composite board 40.

The conductive pillars 43 are formed in the through holes 400 to electrically connect to the wiring layers 41.

In one embodiment, the plurality of first board structures 1, the second board structure 2 and the third board structure 3 include glass boards.

In one embodiment, the plurality of first board structures 1, the second board structure 2 and/or the third board structure 3 have circuit layers electrically connected to the conductive pillars 43.

In one embodiment, the plurality of first board structures 1, the second board structure 2 and the third board structure 3 are bonded to each other by insulating layers thereof.

In one embodiment, the first board structures 1 are formed with the first vias 100 penetrating the first board body 10, and the first circuit layers 11 are formed on two opposite surfaces of the first board body 10. For example, the first insulating layers 12 covering the first circuit layers 11 are formed on the two opposite surfaces of the first board body 10.

In one embodiment, the second board structure 2 is formed with the second vias 200 penetrating the second board body 20, and a second circuit layer 21 is formed on one surface of the second board body 20. For example, the second insulating layer 22 are formed on two opposite surfaces of the second board body 20, and thus the second circuit layer 21 is covered by the second insulating layer 22 on one of the two opposite surfaces.

In one embodiment, the third board structure 3 is formed with the third vias 300 penetrating the third board body 30, and the third circuit layer 31 is formed on one surface of the third board body 30. For example, the third insulating layer 32 are formed on two opposite surfaces of the third board body 30, and thus the third circuit layer 31 is covered by the third insulating layer 32 on one of the two opposite surfaces.

In view of the above, in the carrier substrate and manufacturing method of the present disclosure, a composite board is manufactured by stacking multiple thinner glass board structures to meet the thinning requirements. Accordingly, the structure stability of the carrier structure can be greatly improved through silicon material having the characteristic of resisting warping and deformation. For example, the stress on each layer of the board structure is concentrically distributed, instead of stress gradients toward the edges generated by the conventional organic board. Therefore, the carrier substrate of the present disclosure has better thermal stress resistance under harsh environmental conditions, thereby improving reliability.

The above embodiments are provided for illustrating the principles of the present disclosure and its technical effect and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A carrier substrate, comprising:
a plurality of first board structures containing silicon and having a plurality of first vias;
a second board structure containing silicon and having a plurality of second vias;
a third board structure containing silicon and having a plurality of third vias, wherein the plurality of first board structures, the second board structure and the third board structure are stacked to form a composite board, the plurality of first board structures are positioned between the second board structure and the third board structure, and each of the first vias, the second vias and the third vias are correspondingly connected to each other to form a through hole;
wiring layers formed on two opposite sides of the composite board; and
a plurality of conductive pillars each formed in the through hole and electrically connected to the wiring layers.

2. The carrier substrate of claim 1, wherein the plurality of first board structures, the second board structure and the third board structure comprise glass boards.

3. The carrier substrate of claim 1, wherein the plurality of first board structures, the second board structure and/or the third board structure further have circuit layers electrically connected to the conductive pillars.

4. The carrier substrate of claim 1, wherein the plurality of first board structures, the second board structure and the third board structure are bonded to each other by insulating layers.

5. The carrier substrate of claim 1, wherein the first board structure comprises a first board body with the first vias penetrating the first board structure, and first circuit layers are formed on two opposite surfaces of the first board body.

6. The carrier substrate of claim 5, wherein the two opposite surfaces of the first board body are formed with first insulating layers covering the first circuit layers.

7. The carrier substrate of claim 1, wherein the second board structure comprises a second board body, the second vias penetrating the second board structure, and a second circuit layer formed on one of two opposite surfaces of the second board body.

8. The carrier substrate of claim 7, wherein the two opposite surfaces of the second board body are formed with a second insulating layer, and the second circuit layer is covered by the second insulating layer on one of the two opposite surfaces.

9. The carrier substrate of claim 1, wherein the third board structure comprises a third board body, the third vias penetrating the third board structure, and a third circuit layer formed on one of two opposite surfaces of the third board body.

10. The carrier substrate of claim 9, wherein the two opposite surfaces of the third board body are formed with third insulating layers, and the third circuit layer is covered by the third insulating layer on one of the two opposite surfaces.

11. A method of manufacturing a carrier substrate, comprising:
providing a plurality of first board structures containing silicon and having a plurality of first vias, a second board structure containing silicon and having a plurality of second vias and a third board structure containing silicon and having a plurality of third vias;
stacking the plurality of first board structures, the second board structure and the third board structure to form a composite board, wherein the plurality of first board structures are interposed between the second board structure and the third board structure, and each of the first vias, the second vias and the third vias are connected to each other to form a through hole; and
forming wiring layers on two of opposite sides of the composite board, and forming at least one conductive pillar electrically connected to the wiring layers in the through hole.

12. The method of claim 11, wherein the plurality of first board structures, the second board structure and the third board structure comprise glass boards.

13. The method of claim 11, wherein the plurality of first board structures, the second board structure and/or the third board structure have circuit layers electrically connected to the conductive pillar.

14. The method of claim 11, wherein the plurality of first board structures, the second board structure and the third board structure are bonded to each other by insulating layers.

15. The method of claim 11, wherein the first board structure comprises a first board body, the first vias penetrating the first board structure, and first circuit layers formed on two opposite surfaces of the first board body.

16. The method of claim 15, wherein the two opposite surfaces of the first board body are formed with first insulating layers covering the first circuit layers.

17. The method of claim 11, wherein the second board structure comprises a second board body, the second vias penetrating the second board structure, and a second circuit layer formed on one of two opposite surfaces of the second board body.

18. The method of claim 17, wherein the two opposite surfaces of the second board body are formed with second insulating layers, and the second circuit layer is covered by the second insulating layer on one of the two opposite surfaces.

19. The method of claim 11, wherein the third board structure comprises a third board body, the third vias penetrating the third board structure, and a third circuit layer formed on one of two opposite surfaces of the third board body.

20. The method of claim 19, wherein the two opposite surfaces of the third board body are formed with third insulating layers, and the third circuit layer is covered by the third insulating layer on one of the two opposite surfaces.
